(19) United States
(12) Patent Application Publication
(10) Pub. No.: US 2014/0359397 A1
(43) Pub. Date: Dec. 4, 2014

(54) MEMORY ACCESS APPARATUS AND METHOD FOR INTERLEAVING AND DEINTERLEAVING

(71) Applicant: Electronics and Telecommunications Research Institute, Daejeon (KR)

(72) Inventor: Duck-Hwan KIM, Daejeon (KR)

(73) Assignee: Electronics and Telecommunications Research Institute, Daejeon (KR)

(21) Appl. No.: 14/262,936

(22) Filed: Apr. 28, 2014

(30) Foreign Application Priority Data
May 29, 2013 (KR) 10-2013-0060812

(51) Int. Cl. H03M 13/27; G06F 11/10

(52) U.S. Cl. CPC H03M 13/276; G06F 11/1076
USPC 714/764

(57) ABSTRACT

A memory access apparatus and method for interleaving and deinterleaving are disclosed herein. The memory access apparatus includes a memory module unit, a block selection unit, and an address assignment unit. The memory module unit includes a plurality of pieces of memory for storing data interleaved by a first interleaver and a second interleaver using data decoded by a first decoder, and data deinterleaved by a deinterleaver using data decoded by a second decoder. The block selection unit selects any one of a plurality of memory blocks included in any one of the plurality of pieces of memory in response to the reception of an output signal for storing the interleaved or deinterleaved data in the memory module unit. The address assignment unit assigns an address to the output signal.

### CROSS REFERENCE TO RELATED APPLICATION

This application claims the benefit of Korean Patent Application No. 10-2013-0060812, filed on May 29, 2013, which is hereby incorporated by reference in its entirety into this application.

### BACKGROUND OF THE INVENTION

1. Technical Field

The present invention relates generally to a memory access apparatus and method for interleaving and deinterleaving and, more particularly, to a memory access apparatus and method for interleaving and deinterleaving, which are capable of performing memory access at the same time during interleaving and deinterleaving processes.

2. Description of the Related Art

An interleaver is a device having a function of correcting errors that may frequently occur in wireless communication using memory, and functions to extend error occurrence time within the range of the correction function.

A high-speed digital communication system including a wireless terminal, such as a next-generation WLAN, chiefly uses a block interleaver among various types of interleavers.

A block interleaver uses a forward error correction method for detecting a bit error on a receiving side in order to prevent the bit error generated because of channel distortion, and is interleaving technology essentially required for a wireless communication channel environment.

A conventional technology using a block interleaver is a technology disclosed in Korean Patent Application Publication No. 10-2004-0050935 entitled “Address Counting Apparatus and Method for Reading of Block Interleaver.” This conventional technology discloses an address counting apparatus and method for reading, in which an algorithm for enabling an interleaver having a pattern varying depending on the interval between the transmitted signals of an asynchronous terminal system to read data from memory is simplified, thereby rapidly processing a memory read operation.

In general, an interleaver used in a WLAN includes a single piece of memory that is time-divided and used. A write control block, a read control block, and blocks for controlling the entire interleaver are responsible for access to the memory.

In this case, the write control block and the read control block perform memory write control and memory read control under the control of all the control blocks. The write control block is implemented using an algorithm having a simple method of writing data into the memory, whereas the read control block is implemented using an algorithm having a complicated method of reading data from the memory.

The conventional interleaver is problematic in that it does not perform flexible data processing in connection with varying packet data transfer rate and the consumption power of memory is high upon handling a large number of interleaving processes.

### SUMMARY OF THE INVENTION

Accordingly, the present invention has been made keeping in mind the above problems occurring in the conventional art, and an object of the present invention is to provide a memory access apparatus and method for interleaving and deinterleaving, in which memory is divided into a plurality of memory blocks corresponding to the outputs of interleavers and a deinterleaver and thus memory access can be performed at the same time during interleaving and deinterleaving processes.

In accordance with an aspect of the present invention, there is provided a memory access apparatus for interleaving and deinterleaving, including a memory module unit configured to include a plurality of pieces of memory for storing data interleaved by a first interleaver and a second interleaver using data decoded by a first decoder, and data deinterleaved by a deinterleaver using data decoded by a second decoder; a block selection unit configured to select any one of a plurality of memory blocks included in any one of the plurality of pieces of memory in response to the reception of an output signal for storing the interleaved or deinterleaved data in the memory module unit; and an address assignment unit configured to assign an address to the output signal.

The second decoder may receive and decode the data decoded by the first decoder using the data interleaved by the first interleaver and the second interleaver; and the first decoder may receive and decode the data decoded by the second decoder using the data deinterleaved by the deinterleaver.

The plurality of pieces of memory may be assigned to the first interleaver, the second interleaver and the deinterleaver so that the amount of memory assigned to each of the first interleaver, the second interleaver and the deinterleaver corresponds to the size of the matrix of each of the first interleaver, the second interleaver and the deinterleaver.

Each of the plurality of pieces of memory may include a first memory block for storing the data interleaved by the first interleaver using the data decoded by the first decoder; a second memory block for storing the data interleaved by the second interleaver using input data having a systematic symbol; a third memory block for storing the data deinterleaved by the deinterleaver using the data decoded by the second decoder; a fourth memory block for storing the data interleaved by the first interleaver using the data decoded by the first decoder; a fifth memory block for storing the data interleaved by the second interleaver using the input data of the systematic symbol; and a sixth memory block for storing the data deinterleaved by the deinterleaver using the data decoded by the second decoder.

The memory module unit may store the interleaved or deinterleaved data, corresponding to the output signal, in a memory block of memory that match a selection signal generated by the block selection unit and an address signal generated by the address assignment unit.

The address assignment unit may output an address signal including information about the memory number of the any one of the plurality of pieces of memory that is assigned based on a sequential position at which the output signal is output.

The block selection unit may output a selection signal including information about the any one of the plurality of memory blocks.

The memory access apparatus may further include a data transmission unit configured to send the interleaved or deinterleaved data to the memory module unit and to send the interleaved or deinterleaved data stored in the memory module unit to any one of the first interleaver, the second interleaver and the deinterleaver.

In accordance with another aspect of the present invention, there is provided a memory access method for interleaving and deinterleaving, including providing, by a memory module unit, a plurality of pieces of memory configured to store data interleaved by a first interleaver or a second interleaver using data decoded by a first decoder, and data deinterleaved by a deinterleaver using data decoded by a second decoder; selecting, by a block selection unit, any one of a plurality of memory blocks included in any one of the plurality of pieces of memory in response to reception of an output signal for storing the interleaved or deinterleaved data in the memory module unit; and assigning, by an address assignment unit, an address to the output signal.

Providing the plurality of pieces of memory configured to store the data interleaved by the first interleaver or the second interleaver using the data decoded by the first decoder, and the data deinterleaved by the deinterleaver using the data decoded by the second decoder may include assigning the plurality of pieces of memory to the first interleaver, the second interleaver and the deinterleaver so that the amount of memory assigned to each of the first interleaver, the second interleaver and the deinterleaver corresponds to the size of the matrix of each of the first interleaver, the second interleaver and the deinterleaver.

Providing the plurality of pieces of memory configured to store the data may include providing each of the plurality of pieces of memory with a first memory block for storing the data interleaved by the first interleaver using the data decoded by the first decoder, a second memory block for storing the data interleaved by the second interleaver using input data having a systematic symbol, a third memory block for storing the data deinterleaved by the deinterleaver using the data decoded by the second decoder, a fourth memory block for storing the data interleaved by the first interleaver using the data decoded by the first decoder, a fifth memory block for storing the data interleaved by the second interleaver using the input data of the systematic symbol, and a sixth memory block for storing the data deinterleaved by the deinterleaver using the data decoded by the second decoder.

Selecting the any one of the plurality of memory blocks included in the any one of the plurality of pieces of memory in response to the reception of the output signal for storing the interleaved or deinterleaved data in the memory module unit may include outputting, by the block selection unit, a selection signal including information about the any one of the plurality of memory blocks.

Assigning the address to the output signal may include outputting, by the address assignment unit, an address signal including information about the memory number of the any one of the plurality of pieces of memory that is assigned based on a sequential position at which the output signal is output.

The memory access method may further include, after assigning the address to the output signal, storing, by the memory module unit, the interleaved or deinterleaved data, corresponding to the output signal, in a memory block of corresponding memory that match a selection signal generated by the block selection unit and an address signal generated by the address assignment unit.

The memory access method may further include sending, by a data transmission unit, the interleaved or deinterleaved data to the memory module unit and also sending the interleaved or deinterleaved data stored in the memory module unit to any one of the first interleaver, the second interleaver and the deinterleaver.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram illustrating the configuration of a turbo decoder according to an embodiment of the present invention;

FIG. 2 is a diagram illustrating the configuration of a memory access apparatus for interleaving and deinterleaving according to an embodiment of the present invention;

FIG. 3 is a diagram illustrating the configuration of memory according to the present invention;

FIG. 4 is a diagram illustrating information about the indices of memory blocks included in memory according to the present invention;

FIG. 5 is a diagram illustrating addresses assigned to a plurality of pieces of memory included in a memory module unit according to an embodiment of the present invention; and

FIG. 6 is a flowchart illustrating a memory access method for interleaving and deinterleaving according to an embodiment of the present invention.

### DESCRIPTION OF THE PREFERRED EMBODIMENTS

Embodiments of the present invention will be described with reference to the accompanying drawings in order to describe the present invention in detail so that those having ordinary knowledge in the technical field to which the present pertains can easily practice the present invention. It should be noted that same reference numerals are used to designate the same or similar elements throughout the drawings. In the following description of the present invention, detailed descriptions of known functions and configurations which are deemed to make the gist of the present invention obscure will be omitted.

A memory access apparatus and method for interleaving and deinterleaving according to embodiments of the present invention are described in detail below with reference to the accompanying drawings.

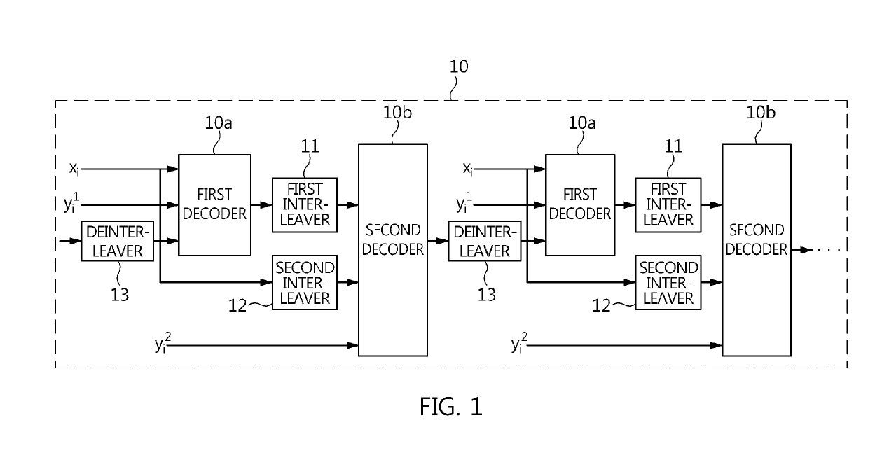

FIG. 1 is a diagram illustrating the configuration of a turbo decoder 10 according to an embodiment of the present invention.

Referring to FIG. 1, the turbo decoder 10 according to this embodiment of the present invention includes a plurality of stages each including a first decoder 10a, a first interleaver 11, a second interleaver 12, a second decoder 10b, and a deinterleaver 13. The first decoder 10a, the second decoder 10b, the first decoder 10a, the second decoder 10b, . . . , sequentially operate.

First, in the first stage of the turbo decoder 10, a signal systematic symbol xₖ, a first parity symbol yₖ, and a second parity symbol yₖ output from a turbo coding apparatus (not shown) are input to the turbo decoder 10. The systematic symbol xₖ and the first parity symbol yₖ are decoded by the first decoder 10a, and data interleaved by the first interleaver 11 and the second interleaver 12 is stored in a memory device 100 (hereinafter referred to as a “memory access apparatus”). In this case, the memory access apparatus 100 stores the data that has been interleaved by the first interleaver 11 and the second interleaver 12.

Furthermore, signals output from the first interleaver 11 and the second interleaver 12 are output to the second decoder 10b. The second decoder 10b performs decoding using the second parity symbol yₖ, and the decoded results of the first decoder 10a, which are stored in the memory access apparatus 100.

As described above, data decoded by the second decoder 10b using the decoded data of the first decoder 10a, stored in the memory access apparatus 100, and the second parity symbol yₖ becomes decoded data for which a single full decoding process has been completed.

The decoded data for which the single full decoding process has been completed is output to the deinterleaver 13. The deinterleaver 13 stores the decoded data, output from the second decoder 10b, that is, the decoded data for which the decoding process has been completed, in the memory access apparatus 100, and outputs the stored decoded data to the first decoder 10a.

Thereafter, the decoded data stored in the memory access apparatus 100, the systematic symbol xₖ, and the first parity symbol yₖ are decoded by the first decoder 10a of a second stage. Data deinterleaved by the first interleaver 11 and the second interleaver 12 of the second stage is stored in the memory access apparatus 100.

Furthermore, signals output from the first interleaver 11 and the second interleaver 12 of the second stage are output to the second decoder 10b of the second stage. The second decoder 10b performs decoding using the second parity symbol yₖ and the recent decoded results of the first decoder 10a, which have been stored in the memory access apparatus 100.

As described above, data decoded by the second decoder 10b using the decoded data of the first decoder 10a, stored in the memory access apparatus 100, and the second parity symbol yₖ becomes decoded data for which two full decoding processes have been completed.

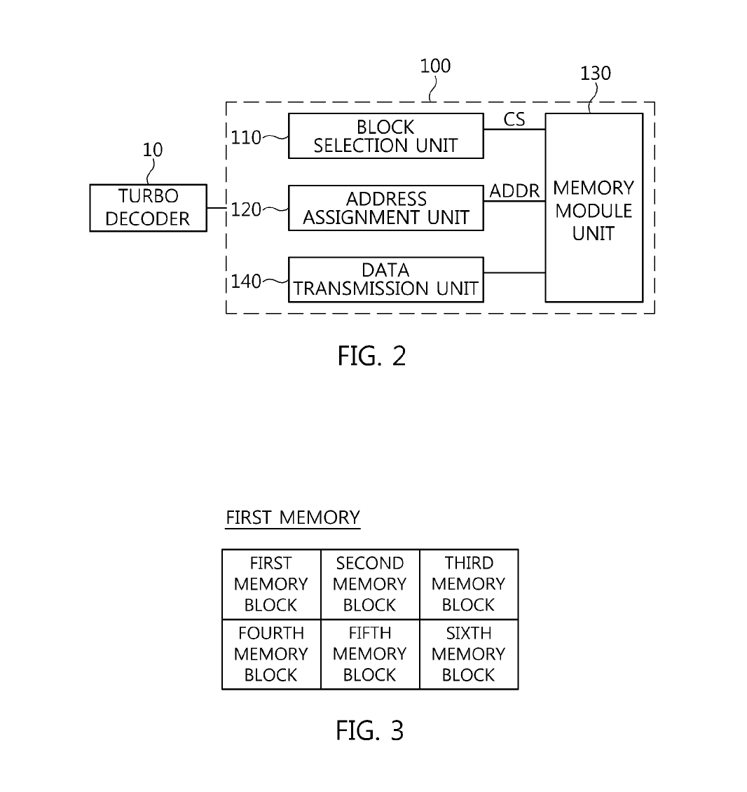

FIG. 2 is a diagram illustrating the configuration of a memory access apparatus for interleaving and deinterleaving according to an embodiment of the present invention.

Referring to FIG. 2, a memory access apparatus 100 according to an embodiment of the present invention basically includes a block selection unit 110, an address assignment unit 120, a memory module unit 130, and a data transmission unit 140 in order to store data interleaved or deinterleaved by the first interleaver 11, the second interleaver 12 and the deinterleaver 13 as described above.

The memory module unit 130 includes a plurality of pieces of memory configured to store data interleaved by the first interleaver 11 or the second interleaver 12 using data decoded by the first decoder 10a, and data deinterleaved by the deinterleaver 13 using data decoded by the second decoder 10b.

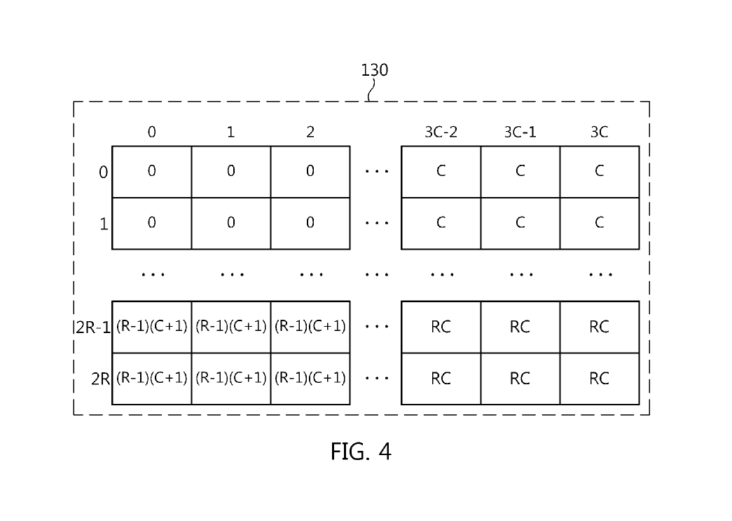

The plurality of pieces of memory is assigned to the first interleaver 11, the second interleaver 12 and the deinterleaver 13 so that the amount of memory assigned to each of the first interleaver 11, the second interleaver 12 and the deinterleaver 13 corresponds to the size of the matrix of each of the first interleaver 11, the second interleaver 12 and the deinterleaver 13. Each of the plurality of pieces of memory is blocked into six memory blocks corresponding to the outputs of the first interleaver 11, the second interleaver 12 and the deinterleaver 13. The configuration of the memory blocks is described in detail later with reference to FIGS. 3 and 4.

Furthermore, the memory module unit 130 stores interleaved or deinterleaved data, corresponding to an output signal, in a memory block of memory that matches a selection signal CS generated by the block selection unit 110 and an address signal ADDR generated by the address assignment unit 120. In this case, the memory module unit 130 has defined information about a memory block and information about an address number corresponding to the selection signal CS and the address signal ADDR in advance.

When an output signal for storing interleaved or deinterleaved data in the memory module unit 130 is received, the block selection unit 110 selects any one of a plurality of memory blocks included in any one of the plurality of pieces of memory. In this case, the block selection unit 110 outputs a selection signal CS, including information about any one of the plurality of memory blocks, to the memory module unit 130.

The address assignment unit 120 assigns an address to the output signal for storing the interleaved or deinterleaved data in the memory module unit 130. In this case, the address assignment unit 120 outputs an address signal ADDR, including information about the memory number of any one of a plurality of pieces of memory that is assigned based on a sequential position at which the output signal is output, to the memory module unit 130.

The data transmission unit 140 sends interleaved or deinterleaved data to the memory module unit 130, and sends the interleaved or deinterleaved data, stored in the memory module unit 130, to any one of the first interleaver 11, the second interleaver 12 and the deinterleaver 13.

FIG. 3 is a diagram illustrating the configuration of memory according to the present invention, and FIG. 4 is a diagram illustrating information about the indices of memory blocks included in memory according to the present invention.

Referring to FIG. 3, each of a plurality of pieces of memory according to the present invention includes six memory blocks as described above. Only the first memory of the plurality of pieces of memory is described below. That is, in the first to nth memory, components having the same component names can perform the same operations. The six memory blocks of the first memory include a first memory block for storing data interleaved by the first interleaver 11 using data decoded by the first decoder 10a, a second memory block for storing data interleaved by the second interleaver 12 using input data having a systematic symbol, a third memory block for storing data deinterleaved by the deinterleaver 13 using data decoded by the second decoder 10b, a fourth memory block for storing the data interleaved by the first interleaver 11 using the data decoded by the first decoder 10a, a fifth memory block for storing the data interleaved by the second interleaver 12 using the input data of the systematic symbol, and a sixth memory block for storing the data deinterleaved by the deinterleaver 13 using the data decoded by the second decoder 10b. Furthermore, as illustrated in FIG. 4, index numbers 0 to 5 are assigned to the respective memory blocks, and may be used as information about the memory blocks.

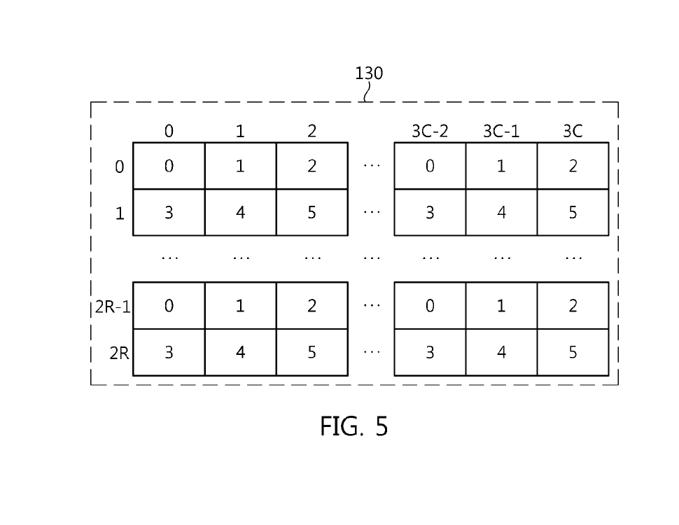

FIG. 5 is a diagram illustrating addresses assigned to a plurality of pieces of memory included in the memory module unit according to an embodiment of the present invention.

Referring to FIG. 5, information about a unique memory number is assigned to each of a plurality of pieces of memory. The plurality of pieces of memory are each assigned information about a memory number that sequentially increases by one based on its sequential position at which it is disposed, that is, based on an increase in sequential position in a row or a column That is, although a method of assigning “0” to first memory and then assigning memory numbers sequentially increasing by one to the remaining pieces of memory has been illustrated in FIG. 1, the present invention is not limited thereto. For example, various methods, such as a method of assigning memory numbers increasing based on any of odd-numbered values and even-numbered values, may be applied to the present invention.

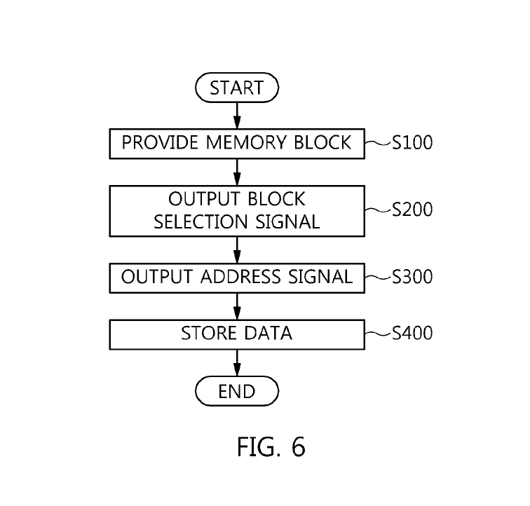

FIG. 6 is a flowchart illustrating a memory access method for interleaving and deinterleaving according to an embodiment of the present invention.

Referring to FIG. 6, the memory access method for interleaving and deinterleaving according to this embodiment of the present invention is a method using the above-described memory access apparatus, and a redundant description is omitted.

First, a plurality of pieces of memory for storing data interleaved by the first interleaver 11 or the second interleaver 12 using data decoded by the first decoder 10a, and data deinterleaved by the deinterleaver 13 using data decoded by the second decoder 10b is provided at step S100. The memory module unit 130 assigns the plurality of pieces of memory to the first interleaver 11, the second interleaver 12 and the deinterleaver 13 so that the amount of memory assigned to each of the first interleaver 11, the second interleaver 12 and the deinterleaver 13 corresponds to the size of the matrix of each of the first interleaver 11, the second interleaver 12 and the deinterleaver 13. Furthermore, each of the plurality of pieces of memory is blocked into six memory blocks: a first memory block for storing data interleaved by the first interleaver 11 using data decoded by the first decoder 10a, a second memory block for storing data interleaved by the second interleaver 12 using input data having a systematic symbol, a third memory block for storing data deinterleaved by the deinterleaver 13 using data decoded by the second decoder 10b, a fourth memory block for storing the data interleaved by the first interleaver 11 using the data decoded by the first decoder 10a, a fifth memory block for storing the data interleaved by the second interleaver 12 using the input data of the systematic symbol, and a sixth memory block for storing the data deinterleaved by the deinterleaver 13 using the data decoded by the second decoder 10b.

Next, when an output signal for storing interleaved or deinterleaved data in the memory module unit 130 is received, any one of the six memory blocks included in any one of the plurality of pieces of memory is selected at step S200. The block selection unit 110 outputs a selection signal CS, including information about the selected memory block, to the memory module unit 130.

Thereafter, an address is assigned to the output signal at step S300. The address assignment unit 120 outputs an address signal ADDR including information about the memory number of the corresponding memory that is assigned based a sequential position at which the output signal is output.

Finally, interleaved or deinterleaved data corresponding to the output signal is stored in a memory block of corresponding memory that matches the selection signal CS generated by the block selection unit 110 and the address signal ADDR generated by the address assignment unit 120 at step S400. In this case, the data transmission unit 140 sends the interleaved or deinterleaved data to the memory module unit 130, and also sends the interleaved or deinterleaved data stored in the memory module unit 130 to any one of the first interleaver 11, the second interleaver 12 and the deinterleaver 13.

As described above, in accordance with an embodiment of the present invention, memory is divided into a plurality of memory blocks corresponding to the outputs of the interleavers and the deinterleaver, and thus memory access can be performed at the same time during an interleaving and deinterleaving process. Accordingly, the present invention is advantageous in that the size of memory can be reduced and a delay time attributable to memory access can be reduced.

Furthermore, the present invention is advantageous in that power consumed by memory can be reduced because memory access can be performed at the same time during interleaving and deinterleaving processes.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A memory access apparatus for interleaving and deinterleaving, comprising:
a memory module unit configured to include a plurality of pieces of memory for storing data interleaved by a first interleaver and a second interleaver using data decoded by a first decoder, and data deinterleaved by a deinterleaver using data decoded by a second decoder;
a block selection unit configured to select any one of a plurality of memory blocks included in any one of the plurality of pieces of memory in response to reception of an output signal for storing the interleaved or deinterleaved data in the memory module unit; and
an address assignment unit configured to assign an address to the output signal.

2. The memory access apparatus of claim 1, wherein:
the second decoder receives and decodes the data decoded by the first decoder using the data interleaved by the first interleaver and the second interleaver; and
the first decoder receives and decodes the data decoded by the second decoder using the data deinterleaved by the deinterleaver.

3. The memory access apparatus of claim 1, wherein the plurality of pieces of memory is assigned to the first interleaver, the second interleaver and the deinterleaver so that an amount of memory assigned to each of the first interleaver, the second interleaver and the deinterleaver corresponds to a size of a matrix of each of the first interleaver, the second interleaver and the deinterleaver.

4. The memory access apparatus of claim 1, wherein each of the plurality of pieces of memory comprises:
a first memory block for storing the data interleaved by the first interleaver using the data decoded by the first decoder;
a second memory block for storing the data interleaved by the second interleaver using input data of a systematic symbol;
a third memory block for storing the data deinterleaved by the deinterleaver using the data decoded by the second decoder;
a fourth memory block for storing the data interleaved by the first interleaver using the data decoded by the first decoder;
a fifth memory block for storing the data interleaved by the second interleaver using the input data of the systematic symbol; and
a sixth memory block for storing the data deinterleaved by the deinterleaver using the data decoded by the second decoder.

5. The memory access apparatus of claim 1, wherein the memory module unit stores the interleaved or deinterleaved data, corresponding to the output signal, in a memory block of memory that match a selection signal generated by the block selection unit and an address signal generated by the address assignment unit.

6. The memory access apparatus of claim 1, wherein the address assignment unit outputs an address signal including information about a memory number of the any one of the plurality of pieces of memory that is assigned based on a sequential position at which the output signal is output.

7. The memory access apparatus of claim 1, wherein the block selection unit outputs a selection signal including information about the any one of the plurality of memory blocks.

8. The memory access apparatus of claim 1, further comprising a data transmission unit configured to send the interleaved or deinterleaved data to the memory module unit and to send the interleaved or deinterleaved data stored in the memory module unit to any one of the first interleaver, the second interleaver and the deinterleaver.

9. A memory access method for interleaving and deinterleaving, comprising:
providing, by a memory module unit, a plurality of pieces of memory configured to store data interleaved by a first interleaver or a second interleaver using data decoded by a first decoder, and data deinterleaved by a deinterleaver using data decoded by a second decoder;
selecting, by a block selection unit, any one of a plurality of memory blocks included in any one of the plurality of pieces of memory in response to reception of an output signal for storing the interleaved or deinterleaved data in the memory module unit; and
assigning, by an address assignment unit, an address to the output signal.

10. The memory access method of claim 9, wherein providing the plurality of pieces of memory configured to store the data interleaved by the first interleaver or the second interleaver using the data decoded by the first decoder, and the data deinterleaved by the deinterleaver using the data decoded by the second decoder comprises assigning the plurality of pieces of memory to the first interleaver, the second interleaver and the deinterleaver so that an amount of memory assigned to each of the first interleaver, the second interleaver and the deinterleaver corresponds to a size of a matrix of each of the first interleaver, the second interleaver and the deinterleaver.

11. The memory access method of claim 9, wherein providing the plurality of pieces of memory configured to store the data comprises providing each of the plurality of pieces of memory with a first memory block for storing the data interleaved by the first interleaver using the data decoded by the first decoder, a second memory block for storing the data interleaved by the second interleaver using input data having a systematic symbol, a third memory block for storing the data deinterleaved by the deinterleaver using the data decoded by the second decoder, a fourth memory block for storing the data interleaved by the first interleaver using the data decoded by the first decoder, a fifth memory block for storing the data interleaved by the second interleaver using the input data of the systematic symbol, and a sixth memory block for storing the data deinterleaved by the deinterleaver using the data decoded by the second decoder.

12. The memory access method of claim 9, wherein selecting the any one of the plurality of memory blocks included in the any one of the plurality of pieces of memory in response to the reception of the output signal for storing the interleaved or deinterleaved data in the memory module unit comprises outputting, by the block selection unit, a selection signal including information about the any one of the plurality of memory blocks.

13. The memory access method of claim 9, wherein assigning the address to the output signal comprises outputting, by the address assignment unit, an address signal including information about a memory number of the any one of the plurality of pieces of memory that is assigned based on a sequential position at which the output signal is output.

14. The memory access method of claim 9, further comprising, after assigning the address to the output signal, storing, by the memory module unit, the interleaved or deinterleaved data, corresponding to the output signal, in a memory block of corresponding memory that match a selection signal generated by the block selection unit and an address signal generated by the address assignment unit.

15. The memory access method of claim 9, further comprising sending, by a data transmission unit, the interleaved or deinterleaved data to the memory module unit and also sending the interleaved or deinterleaved data stored in the memory module unit to any one of the first interleaver, the second interleaver and the deinterleaver.
